(19) United States
(12) Patent Application Publication
(10) Pub. No.: US 2025/0323006 A1
(43) Pub. Date: Oct. 16, 2025

(54) ELECTRON BEAM DEVICE FOR SURFACE TREATMENT

(71) Applicant: CAMECA, GENNEVILLIERS (FR)

(72) Inventor: Pascal SORTAIS, GENNEVILLIERS (FR)

(21) Appl. No.: 18/868,585

(22) PCT Filed: May 25, 2023
(86) PCT No.: PCT/EP2023/064077

§ 371 Date: Nov. 22, 2024

(30) Foreign Application Priority Data
May 30, 2022 (FR) 22/05110

(51) Int. Cl. H01J 37/06; C23C 14/46; H01J 37/141; H01J 37/34

(52) U.S. Cl. CPC H01J 37/06; C23C 14/46; H01J 37/141; H01J 37/3414; H01J 37/345; H01J 2237/04922; H01J 2237/152; H01J 2237/332

(57) ABSTRACT

The present description concerns an electron beam device (100) comprising:
a treatment chamber (130) having a longitudinal direction (Z);
at least one electron beam source (110), each source being adapted to emitting an electron beam in a beam plane (PF) substantially transverse to the longitudinal direction so as to induce a plasma or an evaporation point in the treatment chamber for the treatment of a surface of a part (106);
at least one first port (122) for the passage of the electron beam into said treatment chamber, the diameter of the minimum circle in which said first port is inscribed being smaller than or equal to one eighth, for example smaller than or equal to one tenth, of the smallest dimension (D3) of a transverse cross-section of the treatment chamber taken in the beam plane.

### TECHNICAL FIELD

The present disclosure generally concerns an electron beam device for the treatment of a surface, for example for the deposition of a thin layer on a surface, the cleaning, layer densification, and/or surface etching.

### PRIOR ART

The treatment of a surface, for example a substrate surface, or more generally a surface of a part, generally corresponds to a mechanical, chemical, electrochemical, and/or physical operation which results in modifying the appearance or the function of the surface in order to adapt it to given conditions of use. By extension, in the following disclosure, etching techniques are included in surface treatment.

Surface treatment includes techniques for coating a surface, for example metal coating techniques, and in particular techniques of deposition of a thin film on a surface.

There exist different techniques for performing a thin film deposition on a surface, for example a surface of a substrate, in particular physical vapor deposition (PVD) techniques.

Among these techniques, electron beam physical vapor deposition (EBPVD) is a technique of physical vapor deposition in which a target under high vacuum is bombarded by an electron beam, generally emitted by a tungsten filament. The electron beam causes the atoms or molecules from the target to transform into a gaseous phase. At least part of these atoms or molecules then precipitate in solid form on a surface to be treated, covering said surface with a thin film of these precipitated atoms or molecules. A disadvantage of this technique is the degradation of the filament, which may for example result in a non-uniform evaporation rate. Further, a constraint is to have high vacuum, sometimes lower than 10⁻⁴ mbar.

The sputtering technique consists of directing a plasma comprising relatively heavy charged particles, for example argon ions (Ar+) originating from an at least partially ionized argon gas (Ar), towards a target to cause the sputtering of particles of one or more materials forming this target. At least part of these sputtered particles deposit on a surface, for example a surface of a substrate, to form thereon a thin film of the material(s). The plasma may be formed, for example, by applying an electromagnetic radiation to the gas to be ionized at low pressure. A constraint of this technique is to avoid the contamination between the plasma source and the particles sputtering area on the surface, another constraint being to manage relatively high vacuum, for example lower than or equal to 10⁻² mbar.

Further, these different techniques, as well as others not described but known to those skilled in the art, are implemented by dedicated devices, which are generally not versatile, that is, which generally do not enable to pass from one technique to another.

### SUMMARY OF THE INVENTION

There exists a need for a device adapted to surface treatment, which is capable of implementing different techniques (versatile surface treatment device), for example of implementing different thin-film deposition techniques, but also of cleaning a surface, of densifying a surface layer, and/or of performing an etching from a surface.

In particular, it would be desirable to have an electron beam device for the treatment of a surface, wherein the electron beam can be formed without any filament.

An embodiment overcomes all or part of the disadvantages of known surface treatment devices, and in particular of known thin-film deposition devices.

An embodiment provides s an electron beam device comprising:
a treatment chamber having a longitudinal direction;
at least one electron beam source, each source being adapted to emitting an electron beam in a beam plane substantially transverse to the longitudinal direction so as to induce a plasma or an evaporation point in the treatment chamber for the treatment of a surface of a part;
at least one first port for the passage of the electron beam into said treatment chamber, the diameter of the minimum circle in which said first port is inscribed being smaller than or equal to one eighth, for example smaller than or equal to one tenth, of the smallest dimension of a transverse cross-section of the treatment chamber taken in the beam plane.

According to an embodiment, the treatment chamber comprises a target.

According to an embodiment, the treatment chamber comprises a first support base adapted to supporting the target.

According to an embodiment, the first support base is movable.

According to an embodiment, the first support base comprises, or consists of, a crucible, for example a cooled crucible.

According to an embodiment, the treatment chamber comprises a second support base adapted to supporting the part to be treated.

According to an embodiment, the second support base is movable.

According to an embodiment, the at least one electron beam source is external to the treatment chamber.

According to an embodiment, the device comprises a deflection apparatus, such as an electromagnet or a permanent magnet, adapted to deflecting the electron beam in the treatment chamber.

According to an embodiment, the deflection device is movable.

According to an embodiment, the device comprises a pumping chamber coupled to a first vacuum pump and to the treatment chamber, the pumping chamber being adapted to performing a differential vacuum pumping of said treatment chamber.

According to an embodiment, the treatment chamber is delimited by walls forming a cylindrical or parallelepipedal body, and the pumping chamber is positioned against a side wall of the body, inside or outside said body.

According to an embodiment, the pumping chamber is coaxial with the treatment chamber.

According to an embodiment, the at least one first port is between the pumping chamber and the treatment chamber, and the device comprises at least one second port for the passage of the electron beam between the pumping chamber and the at least one electron beam source.

According to an embodiment, the diameter of the minimum circle in which the at least one second port is inscribed is smaller than or equal to one eighth, for example smaller than or equal to one tenth, of the smallest dimension of the transverse cross-section of the treatment chamber taken in the beam plane.

According to an embodiment, the at least one electron beam source comprises an electron generation chamber and a tube between the electron generation chamber and the treatment chamber.

According to an embodiment, the tube is coupled to the electron generation chamber and to the pumping chamber, and the at least one second port is between the pumping chamber and the tube.

According to an embodiment, the at least one electron beam source comprises a focusing device, such as an electromagnet, adapted to focusing the electron beam, and for example to directing it towards the treatment chamber.

According to an embodiment, the device comprises a second vacuum pump coupled to the treatment chamber and/or a third vacuum pump coupled to the at least one electron beam source.

According to an embodiment, the device comprises a plurality of electron beam sources external to the treatment chamber.

According to a specific embodiment, at least two of the electron beam sources are adapted to emitting electrons along two mutually parallel beam planes.

According to an embodiment, the at least one first port, and in certain cases the at least one second port, corresponds to a port of a diaphragm.

According to an embodiment, the device comprises:
a source for biasing the target to a voltage in the range from 0 to 10 kV, preferably from 2 to 5 kV; and/or
an element for cooling the target.

An embodiment provides an electron beam device comprising:
a treatment chamber having a longitudinal direction;
at least one electron beam source, each source being adapted to emitting an electron beam in a beam plane substantially transverse to the longitudinal direction so as to induce a plasma or an evaporation point in the treatment chamber for the treatment of a surface of a part; said at least one electron beam source being external to the treatment chamber;
a pumping chamber coupled to a first vacuum pump, to the treatment chamber, and to the at least one electron beam source, the pumping chamber being positioned between said treatment chamber and said at least one electron beam source, and being adapted to performing a differential vacuum pumping of said treatment chamber;
at least one first port for the passage of the electron beam between the treatment chamber and the pumping chamber; and
at least one second port for the passage of the electron beam between the pumping chamber and the at least one electron beam source.

According to an embodiment,
the diameter of the minimum circle in which the at least one first port is inscribed is smaller than or equal to one eighth, for example smaller than or equal to one tenth, of the smallest dimension of a transverse cross-section of the treatment chamber taken in the beam plane; and/or
the diameter of the minimum circle in which the at least one second port is inscribed is smaller than or equal to one eighth, for example smaller than or equal to one tenth, of the smallest dimension of the transverse cross-section of the treatment chamber taken in the beam plane.

According to an embodiment, the at least one first port is positioned in a side wall of the treatment chamber so that an electron beam emitted by the at least one electron beam source can penetrate through said at least one first port into said treatment chamber.

According to an embodiment, the at least one second port is positioned in a side wall of the pumping chamber so that an electron beam emitted by the at least one electron beam source can penetrate through said at least one second port into said pumping chamber.

According to an embodiment, the at least one electron beam source, the treatment chamber, and the pumping chamber form a closed assembly.

According to an embodiment, the treatment chamber comprises a target adapted to, under the effect of the electron beam or of the plasma, emitting particles towards the part so as to induce a process of thin-film deposition on said part by a sputtering technique or an electron beam vapor deposition technique.

According to an embodiment, the treatment chamber comprises a first support base adapted to supporting the target, said first support base being for example movable.

According to an embodiment, the first support base comprises, or consists of, a crucible, for example a cooled crucible.

According to an embodiment, the device further comprises:
a source for biasing the target to a voltage in the range from 0 to 10 kV, preferably from 2 to 5 kV; and/or
an element for cooling the target.

According to an embodiment, the treatment chamber comprises a second support base adapted to supporting the part to be treated, said second support base being for example movable.

According to an embodiment, the device comprises a deflection apparatus, such as an electromagnet or a permanent magnet, adapted to deflecting the electron beam in the treatment chamber, said deflection apparatus being for example movable.

According to an embodiment, the treatment chamber is delimited by walls of a cylindrical or parallelepipedal body, and the pumping chamber is positioned against a side wall of the body, inside or outside said body; the pumping chamber being for example coaxial with the treatment chamber.

According to an embodiment, the at least one electron beam source comprises an electron generation chamber and a tube between the electron generation chamber and the treatment chamber; each tube being coupled to the pumping chamber; and the at least one second port being between the pumping chamber and the tube of the at least one electron beam source.

According to an embodiment, the at least one electron beam source comprises a focusing device, such as an electromagnet, adapted to focusing the electron beam, and for example to directing it towards the treatment chamber.

According to an embodiment, the device comprises a second vacuum pump coupled to the treatment chamber and/or a third vacuum pump coupled to the at least one electron beam source.

According to an embodiment, the device comprises a plurality of electron beam sources external to the treatment chamber.

According to an embodiment, at least two of the electron beam sources are adapted to emitting electrons along a same beam plane or along two mutually parallel beam planes.

According to an embodiment, the at least one first port, and/or the at least one second port, corresponds to a port of a diaphragm.

According to an embodiment, the device is adapted to implementing:
a thin-film deposition by sputtering;
a thin-film deposition by electron beam vapor deposition;
a cleaning by means of a plasma;
a layer densification by means of a plasma; and/or
a plasma etching.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 is a simplified cross-section view of an electron beam device according to a first embodiment;

FIG. 2 is a simplified cross-section view of an electron beam device according to a second embodiment;

FIG. 3 is a top view of an electron beam device similar to the device of FIG. 2; and

FIG. 4 is a top view of an electron beam device according to a third embodiment.

### DESCRIPTION OF EMBODIMENTS

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail. In particular, the current or voltage supply systems, the gas supply systems, the systems for possibly biasing the target and/or the surface to be treated, are not detailed, the described embodiments being, unless otherwise specified, compatible with conventional systems. Similarly, the intensity or power supply voltage, or bias voltage, levels, are not detailed.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings or to an electron beam device in a normal position of use.

In the following description, when reference is made to an electron beam plane, or beam plane, it is referred to the plane of emission of one or a plurality of electron beams by one or a plurality of electron beam sources. When there is a plurality of electron beam sources, they can be configured to emit electron beams along one and the same beam plane or along a plurality of beam planes substantially parallel to one another. When reference is made to a longitudinal direction, it is referred to the direction perpendicular to the beam plane(s). A transverse cross-section of a treatment chamber corresponds to a cross-section of the treatment chamber along a plane perpendicular (transverse plane) to the longitudinal direction. When the transverse plane corresponds to a beam plane, it is spoken of a transverse cross-section taken in a beam plane.

Unless specified otherwise, the expressions “about”, “approximately”, “substantially”, and “in the order of” signify plus or minus 10%, preferably of plus or minus 5%.

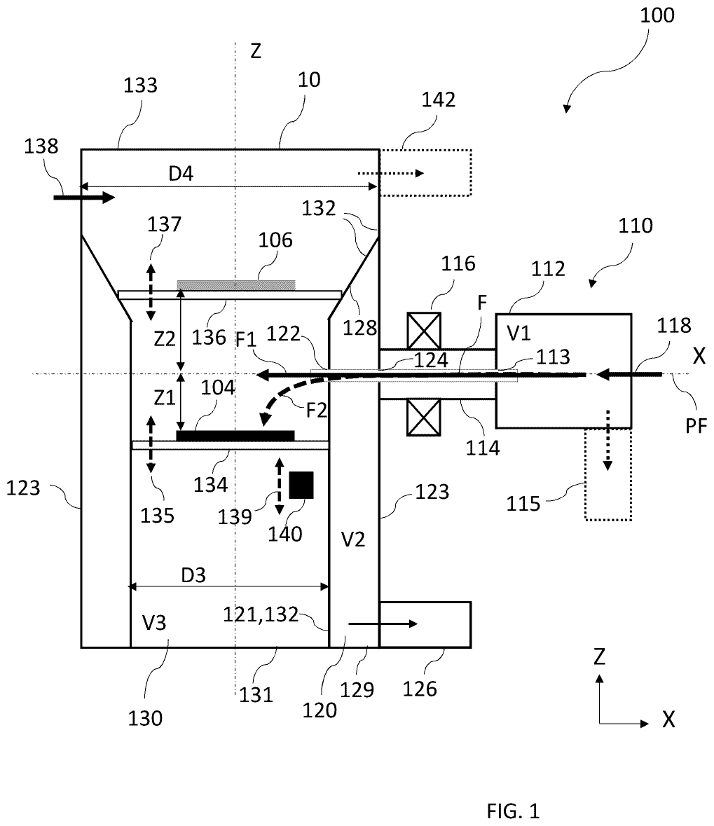

FIG. 1 is a simplified cross-section view of an electron beam device 100 according to a first embodiment.

Device 100 comprises three separate chambers:
an electron generation chamber 112 having a first volume V1;
a pumping chamber 120 having a second volume V2; and
a treatment chamber 130 having a third volume V3.

Electron generation chamber 112 forms part of an electron beam source 110, or electron source, which is adapted to emitting at least one electron beam F in a direction of a beam plane PF.

Electron beam source 110, treatment chamber 130, and pumping chamber 120 form a closed, preferably tight, assembly.

Pumping chamber 120 is coupled to treatment chamber 130 and to electron beam source 110, and positioned between treatment chamber 130 and electron beam source 110. For example, a common wall separates pumping chamber 120 and treatment chamber 130, and another common wall separates pumping chamber 120 and electron beam source 110.

Electron beam source 110 preferably comprises no filament. Electron beam source 110 may comprise, or consist of, for example, a plasma source in which the plasma is obtained by interaction between a high-frequency electromagnetic radiation and a low-pressure gas, such as the plasma source described in patent application FR3062770A1. Thereby, the plasma source generating electrons, and thus forming an electron source, may be placed in a vacuum different from that of the treatment chamber, providing freedom in the selection of the pressure and/or of the nature of the gas for both the treatment chamber and the plasma source.

In the embodiment of FIG. 1, treatment chamber 130 is located between a cylinder 10 (cylindrical body) and pumping chamber 120.

Treatment chamber 130 is closed by a bottom wall 131, corresponding to a central portion of the lower base of cylinder 10, a top wall 133, corresponding to the upper base of cylinder 10, and a side wall 132, having a first portion common with an upper portion of the side wall of cylinder 10 coupling the lower and upper bases of said cylinder, a second portion common with a top wall 128 of pumping chamber 120, and a third portion common with a first side wall 121 (inner side wall) of pumping chamber 120.

Pumping chamber 120 is, in this embodiment, positioned within cylinder 10 and has a ring shape of same axis as the cylinder.

Pumping chamber 120 is closed by a second side wall 123 (outer side wall) common with a lower portion of the side wall of cylinder 10, inner side wall 121, top wall 128, and a bottom wall 129, the top and bottom walls of the pumping chamber coupling the inner and outer side walls of the pumping chamber. The inner side wall 121 and the top wall 128 of pumping chamber 120 are common with the side wall 132 of treatment chamber 130. The bottom wall 129 of pumping chamber 120 corresponds to a peripheral portion of the lower base of cylinder 10.

Thus, treatment chamber 130 is defined by the space located between cylinder 10 and pumping chamber 120. In other words, the volume V3 of treatment chamber 130 substantially corresponds to the volume of cylinder 10 minus the volume V2 of pumping chamber 120.

The top wall 128 of pumping chamber 120 is shown as oblique with respect to beam plane PF. As a variant, the top wall 128 of pumping chamber 120 may be substantially parallel to beam plane PF. According to another variant, the top wall 128 of pumping chamber 120 may correspond to a portion of the upper base of cylinder 10, that is, the inner wall 121 of pumping chamber 120 may extend all the way to the upper base of cylinder 10.

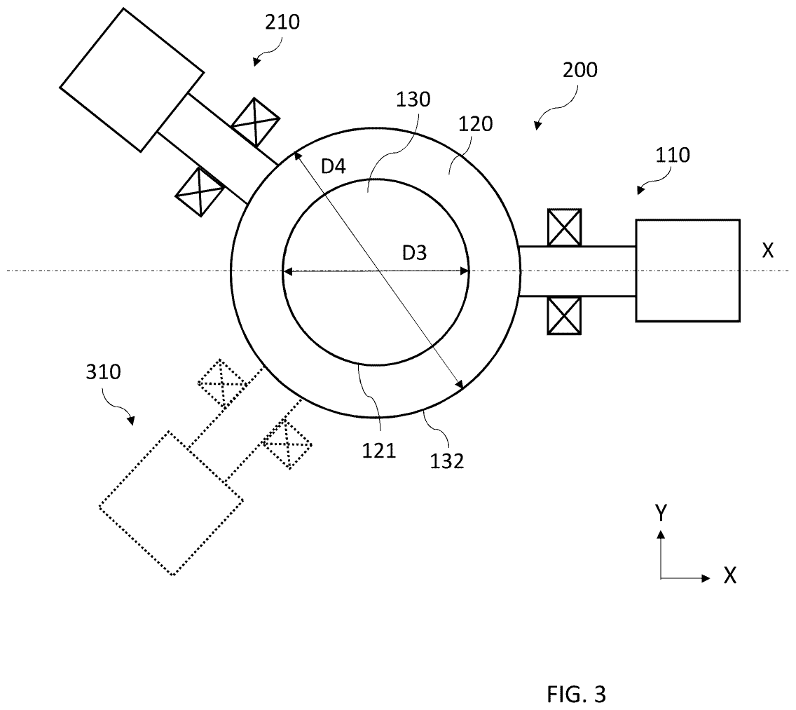

Cylinder 10 is shown as being a straight circular cylinder, as can also be seen in the top view of FIG. 3 described hereafter. The longitudinal direction Z (or axial direction) of treatment chamber 130 corresponds in this mode to the axis of circular cylinder 10. There is designated by D3 the smallest cross-sectional diameter of the portion of treatment chamber 130 surrounded by the pumping chamber (small diameter), and D4 the cross-sectional diameter of the portion of treatment chamber 130 not surrounded by the pumping chamber (large diameter). D3 is smaller than D4.

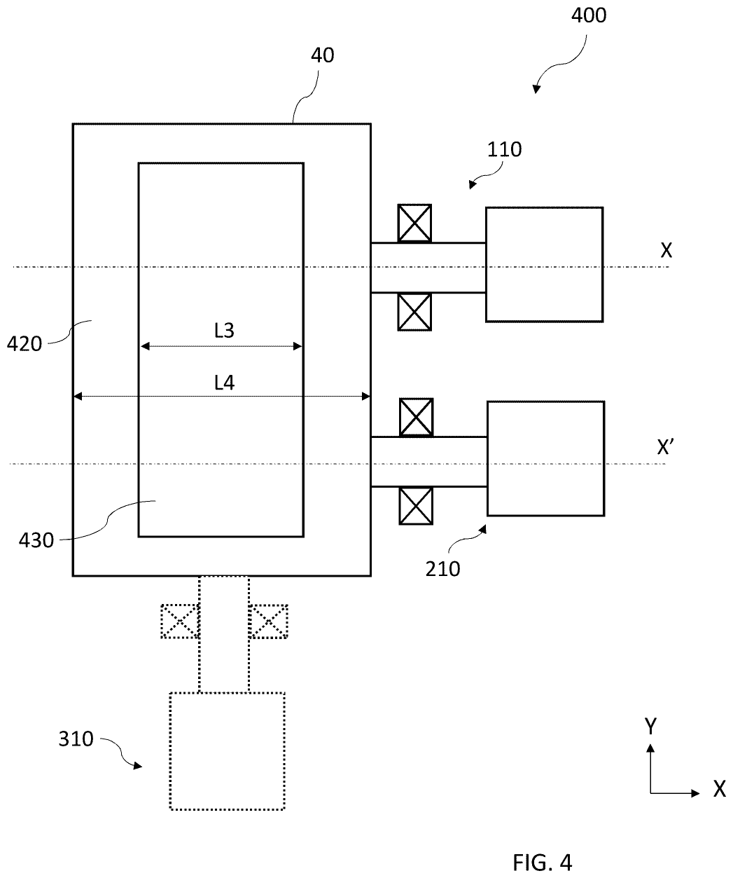

Other shapes and configurations of the treatment chamber and of the pumping chamber are possible. For example, the body may be cylindrical and non-circular, or it may be parallelepipedal, as shown for example in FIG. 4 described hereafter, or may have any other adapted shape. The pumping chamber may be positioned inside or outside this cylindrical or parallelepiped body. For example, the pumping chamber may be positioned outside the body, against a side wall of the body, which then corresponds to a side wall of the treatment chamber.

Pumping chamber 120 is coupled to a first vacuum pump 126. The use of a pumping chamber separate from the treatment chamber allows for a differential pumping.

Further, the fact for pumping chamber 120 to be positioned between treatment chamber 130 and electron beam source 110 forms an intermediate pumping chamber 120 between electron generation chamber 112 and treatment chamber 130. For example, pumping chamber 120 has a pressure P2 intermediate between the pressure P1 in electron generation chamber 112 and the pressure P3 in treatment chamber 130. This makes it possible to differentially set the pressure in electron generation chamber 112, for the production of electrons, and in treatment chamber 130 for the treatment of a substrate 106, as explained hereafter, and thus to optimize the operating pressures in electron generation chamber 112 and in treatment chamber 130.

Treatment chamber 130 comprises a treatment gas inlet 138, coupled to a treatment gas supply (not shown). Examples of treatment gases are rare gases such as He, Ne, Ar, Kr, or Xe or reactive gases such as O₂, N₂, F₂, CH₄, SF₆.

A second vacuum pump 142 may be coupled to treatment chamber 130, for example to control an ultimate vacuum in said treatment chamber, particularly in evaporation mode. The deposition of thin films by evaporation indeed sometimes requires very high vacuums (typically below 10-5 mbar), which may require the presence of a reinforced pumping dedicated to the treatment chamber.

Treatment chamber 130 is adapted to supporting a target 104, for example by means of a first support base 134 assembled inside the treatment chamber. The first support base 134 may be movable along longitudinal direction Z, for example by means of a first motor 135. This may enable to vary a first distance Z1 in the longitudinal direction between target 104 and beam plane PF. More generally, the target may be movable in translation and/or in rotation, for example to control the position and the shape of the wear zone of the target. A single target is shown, but the treatment chamber may contain a plurality of targets, for example a plurality of targets on the first support base.

Target 104 may be placed in a crucible which may form or be part of first support base 134, in particular if it is used in an evaporation deposition technique.

Treatment chamber 130 is adapted to supporting a part, for example a substrate 106, having at least one surface to be treated. A second support base 136 may be assembled inside said treatment chamber in order to support substrate 106. The second support base 136 may be movable in longitudinal direction Z, for example by means of a second motor 137. This may enable to vary a second distance Z2 in the longitudinal direction between substrate 106 and beam plane PF. More generally, the part to be treated may be movable in translation and/or in rotation.

Pumping chamber 120 communicates with treatment chamber 130 by means of a first port 122, and with electron beam source 110 by means of a second port 124. The first and second ports are preferably aligned in the direction electron beam emission (direction X in FIG. 1). Thus, the electron beam emitted by electron beam source 110 in direction X penetrates into treatment chamber 130 via pumping chamber 120 through the first and second ports 122, 124.

In the case where there is a plurality of electron beam emission directions in beam plane PF, a plurality of first and second ports are then preferably provided, each first port being preferably aligned with a second port along one of the emission directions, so that each electron beam emitted in a given emission direction can penetrate into the treatment chamber via the pumping chamber through first and second ports aligned in said emission direction.

First port 122 may be positioned in the inner side wall 121 of pumping chamber 120, that is, in the side wall 132 of treatment chamber 130, and the second port 124 may be positioned in the outer side wall 123 of pumping chamber 120. The inner and outer side walls of the pumping chamber are opposite in emission direction X of the electron beam.

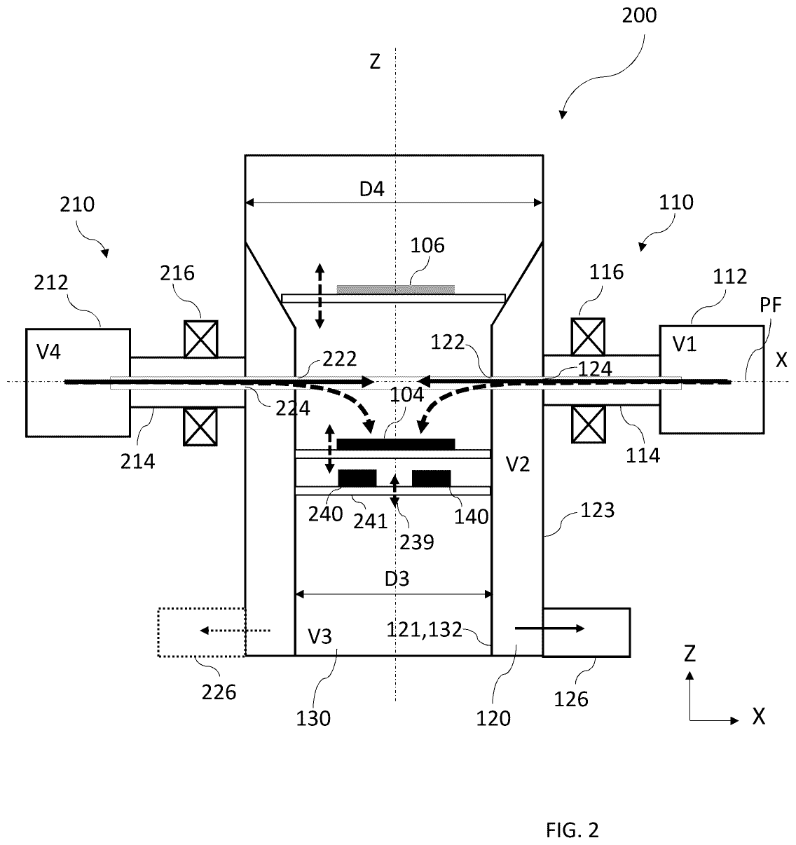

There may be a plurality of first and second ports, particularly if there is a plurality of electron beam sources, as illustrated hereafter in relation with FIG. 2.

In the case where there is a plurality of first and second ports, the first ports may be positioned along a first circumference of the inner side wall 121 of pumping chamber 120, corresponding to a first circumference of the side wall 132 of treatment chamber 130, and the second ports may be positioned along a second circumference of the outer side wall 123 of pumping chamber 120. For example, the first and second circumferences are concentric.

More generally, for example in a variant where the pumping chamber is external to the cylindrical or parallelepipedal body, each first port may be positioned in a wall common to the treatment chamber and the pumping chamber, and each second port may be positioned in another wall common to the pumping chamber and an electron beam source.

As a variant, each first port may be a port of a first diaphragm assembled to the inner side wall of the pumping chamber, that is, to the side wall of the treatment chamber, and/or each second port may be a port of a second diaphragm assembled to the outer side wall of the pumping chamber. The inner side wall may then comprise an opening larger than the first port to integrate the first diaphragm, and/or the outer side wall may then comprise an opening larger than the second port to integrate the second diaphragm. This variant particularly enables to provide variable port sizes according to the targeted application, for example to adjust the fluidic conductance of the port.

The circle of minimum diameter in which each first port 122 is inscribed is adapted to the dimensions of treatment chamber 130, preferably to the dimensions of the transverse cross-section of the treatment chamber taken in the beam plane. The same conditions may apply to the circle of minimum diameter in which the second port 124 is inscribed.

A port may have a circular shape. In this case, the diameter of the circle is taken as the port dimension.

Preferably, the diameter of the minimum circle in which the first port 122 is inscribed is smaller than or equal to ⅛, for example smaller than or equal to 1/10, for example smaller than or equal to 1/12, of the smallest dimension of the transverse cross-section of treatment chamber 130 taken in beam plane PF. In the shown example, this corresponds to the small diameter D3 of treatment chamber 130. The same conditions may apply to the diameter of the minimum circle in which the second port 124 is inscribed.

Such a ratio for a port enables to provide a differential vacuum between electron beam source 110, and in particular electron generation chamber 112, and treatment chamber 130, while minimizing the contamination of the treatment chamber towards electron generation chamber 112. Compromises may be found between the quantity of electrons injected into a beam of given diameter, after focusing, and the maximum dimension of the port, which itself controls the differential pumping.

The first vacuum pump 126 enables to form vacuum in pumping chamber 120, as well as in treatment chamber 130 via the first port 122.

Thus, the first vacuum pump 126, the injection of treatment gas, and in certain cases the second vacuum pump 142, enable to control the pressure in treatment chamber 130.

The pressure in treatment chamber 130 may be adapted according to the treatment technique implemented in the device, for example:
between 10⁻³ mbar and 10⁻¹ mbar for a sputtering deposition;
between 10⁻⁶ mbar and 10⁻¹ mbar for an electron beam vapor deposition.

In the embodiment shown in FIG. 1, electron generation chamber 112 is distant from pumping chamber 120 and from treatment chamber 130. Electron beam source 110 comprises a tube 114, preferably hollow, coupling electron generation chamber 112 and pumping chamber 120. The second port 124 is then positioned between pumping chamber 120 and tube 114. A third passage port 113 is formed between electron generation chamber 112 and tube 114. The third port 113 is preferably aligned with the first and second ports 122, 124 in emission direction X of the electron beam.

As a variant, electron generation chamber 112 may be adjoined to pumping chamber 120 and/or to treatment chamber 130. For example, electron generation chamber 112 may comprise no tube.

Electron beam chamber 112 further comprises a source gas inlet 118 coupled to a source gas supply (not shown). Examples of source gases are rare gases He, Ne, Ar, Kr, or Xe or reactive gases such as O₂, N₂, F₂, CH₄, SF₆.

Electron beam source 110 also preferably comprises an electron beam focusing device. It may be an electrostatic or magnetic focusing device, for example an electromagnet 116 positioned around tube 114 and coupled to a coil power supply (power supply not shown). The focusing device, for example, electromagnet 116, is preferably adapted to generating a magnetic field parallel to the path of the electron beam in tube 114, and may be adapted to conducting said electron beam to treatment chamber 130.

Although this is not shown, electron beam source 110 may comprise an extraction grid and/or an acceleration grid, for example between electron generation chamber 112 and electromagnet 116.

The first vacuum pump 126 may be adapted to forming vacuum in electron generation chamber 112 via pumping chamber 120 and second port 124. The first vacuum pump 126 and the second port 124 may be sized according to the desired vacuum.

As a variant, or complementarily, electron beam source 110 may comprise a third vacuum pump 115 coupled to electron generation chamber 112, and adapted to forming higher vacuum in said chamber, and/or to compensate for a possible retroactive flow originating from treatment chamber 130.

In tube 114, the emitted electron beam F is directed in direction X of beam plane PF, perpendicular to longitudinal direction Z.

For certain applications, the trajectory F1 of the electron beam in treatment chamber 130 may follow the same direction as that of the emitted electron beam, or at least not be directed in a particular direction. For example, the electron beam is not directed towards target 104. The electron beam may be adapted to creating a plasma by means of a treatment gas introduced into the treatment chamber, for example rare gases such as He, Ne, Ar, Kr, or Xe or reactive gases such as O₂, N₂, F₂, CH₄, SF₆. The plasma may be directed towards substrate 106 to clean it and/or to etch it. The plasma may also be directed towards target 104 to tear off particles therefrom, and the particles may be directed towards substrate 106 to perform a thin-film deposition by the sputtering technique.

For other applications, the trajectory F2 of the electron beam in treatment chamber 130 may be deflected to follow a given direction in the treatment chamber. For example, the electron beam may be directed towards target 104. The electron beam may, for example, be adapted to transforming molecules of the target into a gaseous phase. At least part of these molecules then precipitate in solid form onto substrate 106 to perform a thin-film deposition by the electron beam vapor deposition technique.

The device may comprise an electron beam deflection apparatus, for example an electromagnet or a permanent magnet 140, adapted to deflecting the electron beam in treatment chamber 130. The deflection device may be at least partly positioned in the treatment chamber. As a variant, the deflection device may be positioned totally outside the treatment chamber.

The deflection device, for example permanent magnet 140, may be movable along longitudinal direction Z, for example by means of a third motor 139. More generally, the deflection device may be movable in translation and/or in rotation, and thus be able to control or not the trajectory of the electron beams over a very wide energy range thereof, for example between 100 V and 50 kV.

The focusing device, for example electromagnet 126, and the deflection device, for example permanent magnet 140, are preferably adapted to forming magnetic fields having directions transverse, that is, perpendicular, with respect to each other.

The target may be made of copper, tantalum, or a copper or tantalum oxide, or any other solid, or even liquid, material capable of inducing a sputtering or evaporation process, for example a metallic or oxide material.

According to the treatment techniques implemented in the device, the target and/or substrate may be biased. The biasing may typically be of a few tens of volts for the substrate, for example in plasma cleaning or plasma layer densification mode, and/or, for the target, any biasing voltage enabling to obtain energies higher than a sputtering or evaporation threshold, typically in the range from 100 V to 10 kV.

FIG. 2 is a simplified cross-section view of an electron beam device 200 according to a second embodiment, which differs from the device 100 of FIG. 1 in that it comprises a plurality of electron beam sources, a first source 110, and a second source 210 shown in FIG. 2. A first permanent magnet 140 may be adapted to deflecting an electron beam from the first source 110, and a second permanent magnet 240 may be adapted to deflecting an electron beam originating from the second source 210. The permanent magnets may be positioned either each on a support, or on a common support 241, as illustrated, each support being for example movable by means of a motor 239 (common in the illustrated mode). The permanent magnets may be positioned under target 104.

Pumping chamber 120 is positioned between treatment chamber 130 and each of the first 110 and second 210 electron beam sources.

A fourth vacuum pump 226 may be coupled to pumping chamber 120 close to second source 210, as a complement to the first vacuum pump 126, which is preferably coupled close to the first source 110.

Electron beam device 200 comprises at least two first ports 122, 222 and two second ports 124, 224. The first ports 122, 222 are positioned in the inner side wall 121 of the pumping chamber 120, that is, in the side wall 132 of treatment chamber 130 in the shown configuration. The second ports 124, 224 are positioned in the outer side wall 123 of pumping chamber 120.

The first and second ports 122, 124 associated with the first electron beam source 110 are preferably aligned in the direction of electron beam emission by said first source. The first and second ports 222, 224 associated with the second electron beam source 210 are preferably aligned in the direction of electron beam emission by said second source.

Each of the first and second electron beam sources may be similar to the electron beam source 110 of FIG. 1, but the volume V4 of the second electron generation chamber 212 is not necessarily equal to the volume V1 of the first electron generation chamber 112.

In the shown mode, the electron beam sources are positioned so as to emit electrons along substantially the same beam plane PF. As a variant, electron beam sources may be positioned so as to emit electrons along different beam planes parallel to each other.

The other features of the device 200 of FIG. 2 may be similar to those of the device 100 of FIG. 1. Variants described in relation with FIG. 1 may also apply to the device 200 of FIG. 2.

It is possible to have more than two electron beam sources, as well as other vacuum pumps associated with other electron beam sources. The pumping chamber is then positioned between the treatment chamber and each of the electron beam sources. The first and second ports associated with each electron beam source are then preferably aligned in the direction of electron beam emission by said electron beam source.

For example, there has been shown in FIG. 3 a top view of a device similar to the device of FIG. 2, in which a third electron beam source 310 may possibly be positioned.

At least one electron beam source may be adapted to forming electrons at low energy, typically in the range from 0.1 to 2 keV, adapted to plasma cleaning, plasma layer densification, plasma etching, and/or sputtering, and to forming high-power electrons, typically in the range from 2 keV to 30 keV with an intensity typically in the range from 10 to 200 mA per source, more adapted for electron beam vapor deposition.

By multiplying the electron beam sources assembled around the treatment chamber, the general intensity of the formed electrons may be multiplied accordingly.

FIG. 4 is a top view of an electron beam device 400 according to a third embodiment, which differs from the devices 100 and 200 of FIGS. 1 to 3 mainly in that body 40 is parallelepipedal, and not cylindrical. Treatment chamber 430 is delimited by walls of this parallelepipedal body, and by pumping chamber 420, which forms an also parallelepipedal ring, positioned within the parallelepipedal body. According to a variant, not shown, the pumping chamber may be positioned outside the parallelepipedal body against one or plurality of side walls of said body.

The smallest dimension of a transverse cross-section of treatment chamber 430 taken in the beam plane then corresponds to width L3, which corresponds to the width of body L4 minus the width of the pumping chamber.

The shown electron beam sources 110, 210, 310 may be similar to the previously-described sources, and may be positioned so as to emit electrons along a plurality of directions X, X′, Y of a single beam plane PF, or along a plurality of directions of a plurality of beam planes parallel to one another. Further, sources may be positioned on two different side walls of the body, for example two parallel walls and/or two walls perpendicular to each other.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. Electron beam device comprising:
a treatment chamber having a longitudinal direction;
at least one electron beam source, each source being adapted to emitting an electron beam in a beam plane substantially transverse to the longitudinal direction so as to induce a plasma or an evaporation point in the treatment chamber for the treatment a surface of a part; said at least one electron beam source being external to the treatment chamber;
a pumping chamber coupled to a first vacuum pump, to the treatment chamber, and to the at least one electron beam source, the pumping chamber being positioned between said treatment chamber and said at least one electron beam source, and being adapted to performing a differential vacuum pumping of said treatment chamber;
at least one first port for the passage of the electron beam between the treatment chamber and the pumping chamber; and
at least one second port for the passage of the electron beam between the pumping chamber and the at least one electron beam source.

2. Device according to claim 1, wherein:
the diameter of the minimum circle in which the at least one first port is inscribed is smaller than or equal to one eighth, for example smaller than or equal to one tenth, of the smallest dimension of a transverse cross-section of the treatment chamber taken in the beam plane; and/or
the diameter of the minimum circle in which the at least one second port is inscribed is smaller than or equal to one eighth, for example smaller than or equal to one tenth, of the smallest dimension of the transverse cross-section of the treatment chamber taken in the beam plane.

3. Device according to claim 1, wherein the at least one first port is positioned in a side wall of the treatment chamber so that an electron beam emitted by the at least one electron beam source can penetrate through said at least one first port into said treatment chamber.

4. Device according to claim 1, wherein the at least one second port is positioned in a side wall of the pumping chamber so that an electron beam emitted by the at least one electron beam source can penetrate through said at least one second port into said pumping chamber.

5. Device according to claim 1, wherein the at least one electron beam source, the treatment chamber, and the pumping chamber form a closed assembly.

6. Device according to claim 1, wherein the treatment chamber comprises a target adapted to, under the effect of the electron beam or of the plasma, emitting particles towards the part so as to induce a process of thin-film deposition on said part by a sputtering technique or an electron beam vapor deposition technique.

7. Device according to claim 6, wherein the treatment chamber comprises a first support base adapted to supporting the target, said first support base being for example movable.

8. Device according to claim 7, wherein the first support base comprises, or consists of, a crucible, for example a cooled crucible.

9. Device according to claim 8, further comprising:
a source for biasing the target to a voltage in the range from 0 to 10 kV, preferably from 2 to 5 kV; and/or
an element for cooling the target.

10. Device according to claim 1, wherein the treatment chamber comprises a second support base adapted to supporting the part to be treated, said second support base being for example movable.

11. Device according to claim 1, comprising a deflection apparatus, such as an electromagnet or a permanent magnet, adapted to deflecting the electron beam in the treatment chamber, said deflection apparatus being for example movable.

12. Device according to claim 1, wherein the treatment chamber is delimited by walls of a cylindrical or parallelepipedal body, and the pumping chamber is positioned against a side wall of the body, inside or outside said body; the pumping chamber being for example coaxial with the treatment chamber.

13. Device according to claim 11, wherein the at least one electron beam source comprises an electron generation chamber and a tube between the electron generation chamber and the treatment chamber; each tube being coupled to the pumping chamber; and the at least one second port being between the pumping chamber and the tube of the at least one electron beam source.

14. Device according to claim 1, wherein the at least one electron beam source comprises a focusing apparatus, such as an electromagnet, adapted to focusing the electron beam, and for example to directing it towards the treatment chamber.

15. Device according to claim 1, comprising a second vacuum pump coupled to the treatment chamber and/or a third vacuum pump coupled to the at least one electron beam source.

16. Device according to claim 1, comprising a plurality of electron beam sources external to the treatment chamber.

17. Device according to claim 16, wherein at least two of the electron beam sources are adapted to emitting electrons along a single beam plane or along two mutually parallel beam planes.

18. Device according to claim 1, wherein the at least one first port, and/or the at least one second port, corresponds to a port of a diaphragm.

19. Device according to claim 1, wherein the device is adapted to implementing:
a thin-film deposition by sputtering;
a thin-film deposition by electron beam vapor deposition;
a cleaning by means of a plasma;
a layer densification by means of a plasma; and/or
a plasma etching.
